(19) United States
(12) Patent Application Publication
(10) Pub. No.: US 2025/0048540 A1
(43) Pub. Date: Feb. 6, 2025

(54) FLAT MOUNT COMPONENT

(71) Applicant: KEITH JON, STOUGHTON, MA (US)

(72) Inventor: KEITH JON, STOUGHTON, MA (US)

(21) Appl. No.: 18/229,239

(22) Filed: Aug. 2, 2023

(51) Int. Cl. H05K 1/02; H05K 1/11

(52) U.S. Cl. CPC H05K 1/0271; H05K 1/0284; H05K 1/115; H05K 2201/09063

(57) ABSTRACT

Inexpensive to fabricate, inspect and install component used primarily in the mounting of components requiring a precision flat surface condition within an equipment chassis. In particular, the invention significantly reduces high cost and scrap associated with precision flatness not easily produced and inspected in higher volume fabrications. The invention's value should be realized by manufacturers of products—in any volume—comprising components that require precision flat mounting surfaces. More particular the invention eliminates the need for special assembly skills, custom tweaks, or shims to ship product. Most particular this invention saves time and money by mitigating high risk of probability of failure identified in D-FMEA's and P-FMEA's.

### FIELD OF INVENTION

The invention relates to the art of creating flat surface conditions. In particular, the invention relates to the art of simulating a flat surface condition in order to comply with a quality requirement that a component shall be mounted upon a particularly flat surface.

### REFERENCES

U.S. patent Documents: n/a

### BACKGROUND OF INVENTION

This invention addresses particularly flat surface form conditions required for mounting particularly sensitive components within equipment assembly embodiments. Component manufacturers often require compliance with particular flatness requirements when mounting their components on an installation platform so as to ensure effective performance of their component. It's that particular surface form condition onto which a component shall be mounted—not the method of attachment—that the invention targets.

With respect to machine design, particularly an installation platform onto which a component shall be mounted/installed/attached at assembly, the mechanical drawing specification provides a height location dimension of said mounting surface or plane with respect to the chassis base. That particular height dimension has some particular tolerance regulating not only the position of said surface with respect to a datum but—most importantly with respect to the component manufacturer installation requirement—the condition of the mounting surface, i.e.; the high and low limit tolerance of said height location dimension either per standard or specifically called out.

With general reference to ANSI Y14.5, Flatness is interpreted as being a particular condition of a surface having all elements of that surface in one plane regardless of feature size. Maximum material condition, or datum reference is not applicable. Further it's understood flatness tolerance is a form tolerance that can be measured with an indicator which should provide a full indicator reading from high to low points on the surface and where said high and low points must be within the particular drawing specification to be compliant with said specification. Said different conditions of surfaces according to ANSI include variation of form, concave and convex. All said conditions can exist within said size limits as long as the measurements of high and low points fall within said drawing specification. Therefore, it is important to be said part drawing specification addresses all of particular conditions and size limits as necessary to comply with component manufacturer installation requirements.

Now with respect to real world manufacturing—tight specifications often cause problems in operations. That is to say not all processes can produce results specified—at least not cost effectively—or in general practice. In other words, applying a correct specification is one thing but having the part/system interpreted, manufactured, and inspected effectively and efficiently is quite another. Meaning, the problems and cost associated with non-compliant parts can become very difficult to control. Simply put, the tighter the tolerance—the higher risk of failure in part design (D-FMEA) and process (P-FMEA) and the resulting higher cost is important with respect to business.

One application involving the need for a tight tolerance surface form condition involves mounting sensitive electro-mechanical components (EMC's) on a flat installation platform. One particular type of EMC, the Linear Motor (LM) is an excellent example of an EM commonly used in robotic-type laboratory and production equipment embodiments.

Robotic product and manufacturing equipment development is an extremely fast-growing industry resulting in a need for high quantity/volume manufacturing. In turn, high quantity manufacturing of equipment comprising LM's requires more efficient/cost effective materials and processes both in fabrication and inspection of the parts used within said equipment—thus more precision flat installation platforms are needed.

With those precision conditions—produced in higher volume—comes quality challenges and associated problems. Mounting em components (EMC's) effectively and efficiently is generally at the top of the list in risk analysis D-FMEA and P-FMEA documentation. The particular risk concerns related to rail include flex, binding, and position.

First, to understand the need for the invention, it is important to understand the basic mechanical characteristics of Linear Motors (LM,s) with respect to why it's necessary to mount said LM upon an especially particular flat formed installation platform.

Particularly LM's are electro-mechanical components consisting primarily of a motor and rail. LM's operate in the same way as rotary motors that have had their stators rolled out flat or “unwrapped” if you will. The same electromagnetic effects that produce torque in a rotary motor are configured to produce a direct force in a linear motor to move it back and forth along a rail.

More particular LM's are capable of extremely high speeds, quick acceleration, and accurate positioning. That precision is particularly dependent upon the mechanical relationship between said motor and rail. A slip fit is required. Hence any deflection/bending of the rail in assembly or operation may cause binding of said motor which could simply cause excessive wear and/or prohibit operation. Secondly, any lateral movement out of position may cause enough misalignment to render failed operation with respect to accuracy. Therefore, failure in either condition, “deflection” and “positioning” poses a risk of a high probability of failure to some degree and should be recognized in any product development program D-FMEA and/or P-FMEA.

Since reduced size of products is always on Product Developer's User Requirements Specs (URS), LM Design Engineers and customers are no-doubt driven to obtain smaller LM's—effectively it's the smaller the better philosophy. Hence low-profile LM's are demanded by equipment developers and readily presented by most LM manufacturers.

Briefly, low-profile LM's often comprise a vertically thin-in-thickness rail design to reduce height. Because the rail is the component that gets screwed down to the installation platform, a thin rail inefficiently supported will flex/bend easily. More particularly, a thin rail likely has a low Moment of Inertia (Mi)—or at least lower than the integrated Installation platform/equipment assembly embodiment onto which said rail is attached. That Mi difference translates to easy deflection/flexing of the rail under load—if not evenly supported. “Evenly” is the operative word.

First, the “evenly supported” to avoid deflection requirement is addressed in LM Product Performance Specifications (PPS) by requiring the LM Rail be mounted on an exceptionally flat Installation Platform to mitigate the risk of deflection.

Second, the afore mentioned secure “positioning” requirement is addressed by a particular screw torque requirement within said PPS. Both installation requirements shall be found in a respective LM User Manual under Installation Instructions wherein the surface upon which the LM is mounted is commonly identified as the Installation Platform.

Now, with respect to the need for the invention, Equipment Design Engineers must particularly comply with LM manufacturer's installation requirements. So, particularly relative to the invention are 1) a particularly Flat Installation Platform (FIP) to prevent deflection, and 2) Screw Torque Specification to maintain position. To comply with those LM Manufacturer requirements, equipment design engineers apply Geometric Dimension and Tolerance (GDT) on installation platform specification drawings per D-FMEA and apply screw torque specs in assembly procedures per P-FMEA.

Further, with respect to the need for the invention is the cost, quality and operation logistics associated with fabrication and inspection of said FIP when GDT is required. When one or maybe 10 units are produced it might be manageable but when a few hundred or a thousand are ordered—problems are compounded. Particularly when formed sheet metal is used for chassis vs. machined jig plate. Often formed and welded sheet metal chassis produce complicated surface deformations as well as unexpectedly and surprisingly high Moment of Inertia (Mi) values. That is, the inherent strength of said chassis with an integrated installation platform may well be greater than the Mi of the LM rail mounted to it—resulting in a deflected rail when screws are torqued to specification.

Another concern involves medium to high volume manufacturing that introduces more D & P-FMEA issues. In particular some specifications simply cannot be met in Sheetmetal—or at least not easily and cost-effectively. Compromising becomes common and risk escalates. Often inspection is not 100% and/or not effectively validated so defective parts enter assembly lines.

Thereafter when the robot/equipment assembly process commences there is particularly high risk that parts/features have not been inspected or validated effectively and problems escalate. The invention addresses the problem as it relates to the following scenario:

Said LM Motor becomes installed upon said installation platform which is integrated within a robot equipment chassis with screws torqued down to specification. Said robot equipment is built per assembly procedure and final inspection requires a run test in which said LM Motor fails. Trouble shooting uncovers tweaking a couple screws—to less than required torque—solves the problem. Why?—Because the Installation Platform is not flat enough—which caused the rail to flex which caused the motor to bind. Various solutions are discussed include shimming, conical washers, increasing motor current, tweaking screws etc—All essentially make the product non-compliant with company quality policy. Further, pressure to ship product might cause a “do-good” assembly tech to just tweak the screws—a little less than required torque spec to allow the LM to pass final test and ship it. It happens.

Six months later field service techs are struggling with misalignments in the equipment at a number of irate customer facilities. Suddenly the need for an exceptionally precision flat installation platform (FIP) becomes an expensive problem in the corner office. The invention should be an effective solution.

### SUMMARY OF INVENTION

It is an object of this invention, Flat Surface Simulation Hardware Component (FSSHC) to provide a hardware component that effectively simulates a uniformly flat Installation Platform (FIP).

In particular, with understanding “simulation” is generally defined as the imitation of the operation of a real-world process or system condition. With respect to this invention, said uniformly flat installation platform comprises said “condition” and together within equipment embodiment—a “system” shall provide a particular function as part of a system. More particular, it is an object of this invention FSSHC to provide a hardware component that simulates a uniformly flat Installation Platform (FIP)—since FIP's are commonly specified within sensitive em component manufacturers Installation Manuals. Particularly low-profile linear motors (LM) are excellent candidates for FSSHC installation. Therefore, this invention shall use a low-profile LM for example of how the invention is mounted and performs to particularly provide risk mitigation.

In particular, with respect to mounting said LM onto invention FSSHC, the object of this invention shall be to: Mount said linear motor LM, particularly its rail, upon FSSHC and screws shall be torqued to specification. For sake of example—The invention FSSHC shall particularly have an irregular or concave surface for whatever reason. When said rail is installed the irregular surface is evident and shall be analyzed. If the FSSHC was not installed and the LM was attached to a regular installation platform (IP) no the invention—the scenario would cause the rail to deflect when screws are torqued down—the result would be failure due to motor binding on said rail. Should the screws be loosened to facilitate operation—the rail would eventually move out of position laterally and cause equipment failure at a customer facility. Therefore, it is the most particular object of the invention to prevent the rail from flexing by providing an opposing force—as would a flat surface—so as to allow said screws to be tightened to said torque specification.

It is a further object of this invention said FSSHC shall facilitate easy design with respect to specifying, modifying, and adapting FSSHC to equipment system design. So as to mitigate high risk of probability of failure relative to equipment product Design-FMEA. In particular, less precision tolerance is fundamental to efficient design technique.

It is a further object of this invention said FSSHC shall be inexpensive and easy to produce to provide a quality part and assembly. Hence easy to manufacture, inspect and install. Particularly all aspects of product manufacturing shall benefit from the application of a reliable/less precision component, including part fabrication, inspection, assembly test/and final inspection—then further relative to field service/maintenance. The component shall effectively mitigate high risk of probability of failure relative to Process-FMEA. In particular

It is a further object of this invention to be easily modifiable, adaptable and/or integrated into any uniformly flat Installation Platform (UFP) within most any manufacturing environment. In particular, the object of this invention is to provide a hardware component that lends itself easily to low, medium, and high-volume manufacturing. In particular, less precision requirements facilitates efficient manufacturing and quality processes.

It is a further object of this invention to provide a hardware component that lends itself easily to low, medium, and high-volume manufacturing. Particularly, the invention can be very efficiently manufactured in any environment and performance shall remain consistent from one particular application to another.

### BRIEF DESCRIPTION OF THE INVENTION

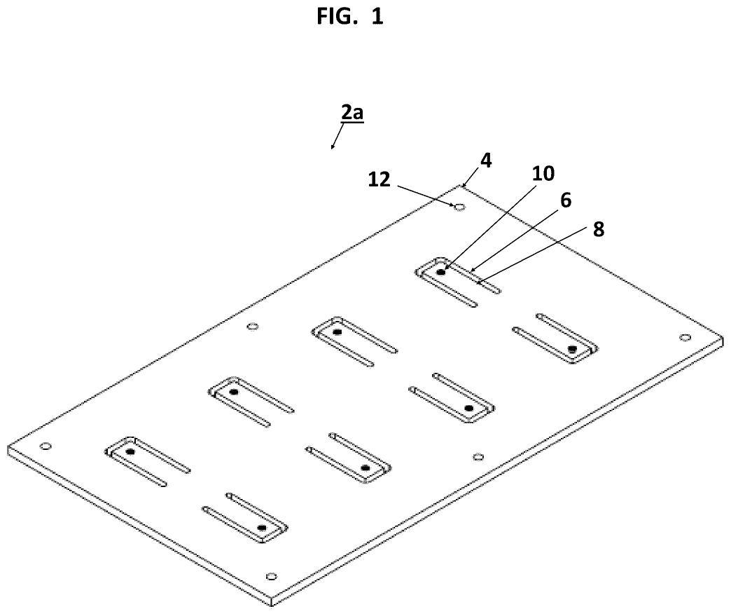

FIG. 1 is an isometric view of a Flat Surface Simulation Hardware Component (FSSHC) according to this invention.

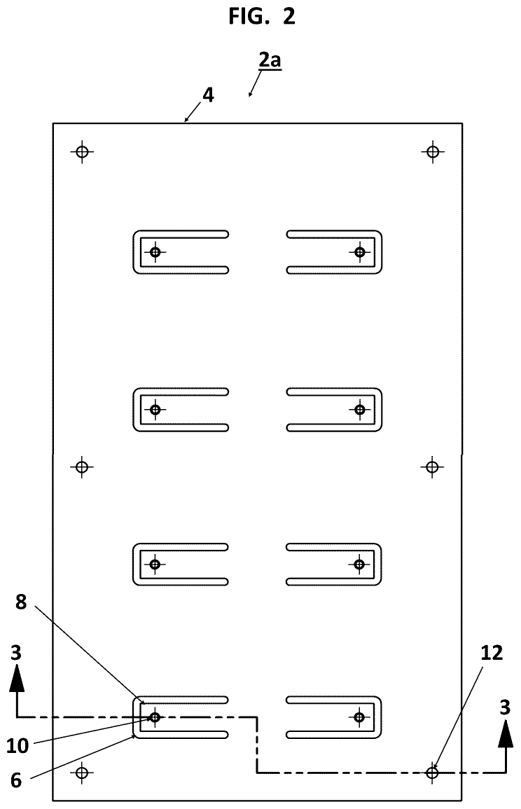

FIG. 2 is a top plan view of the component of FIG. 1.

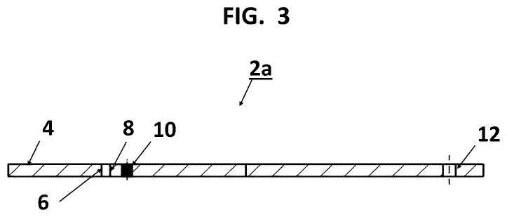

FIG. 3 is a front elevational view in full section depicting the component of FIGS. 1 and 2 along line 3-3 in FIG. 2 according to this invention.

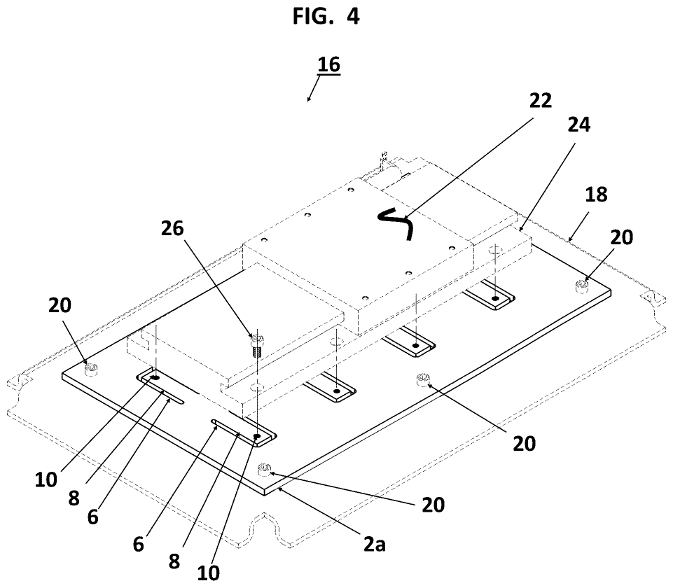

FIG. 4 is an isometric view of a typical equipment assembly embodiment wherein the component of FIGS. 1, 2, and 3 is shown mid process of installation according to this invention.

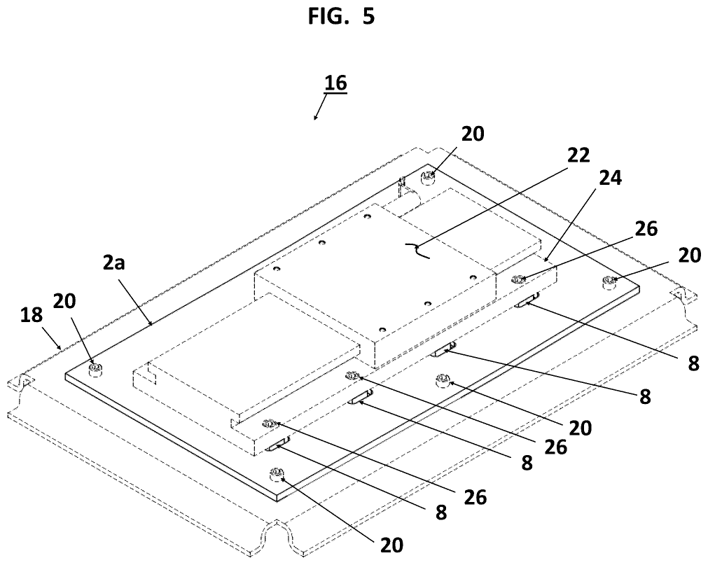

FIG. 5 is an isometric view of a typical equipment assembly embodiment wherein the component of FIGS. 1, 2, and 3 is shown installed according to this invention.

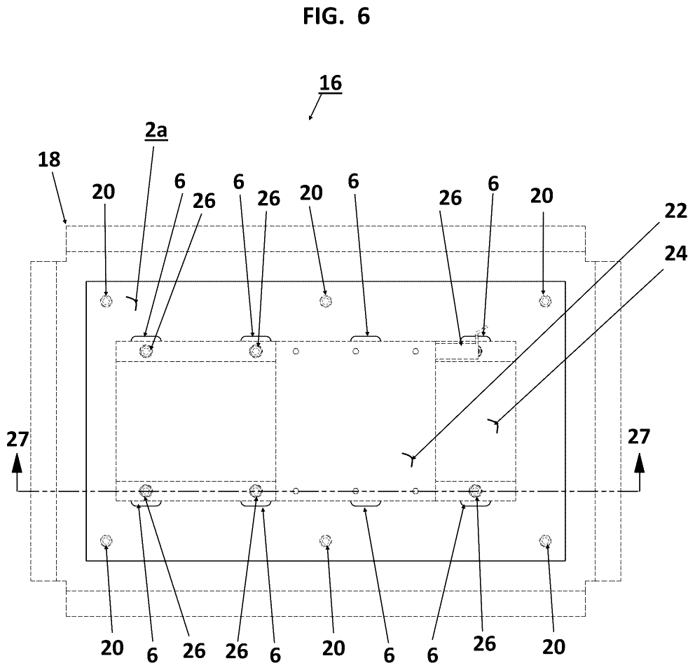

FIG. 6 is a top plan view of the equipment assembly embodiment of FIG. 5 according to this invention.

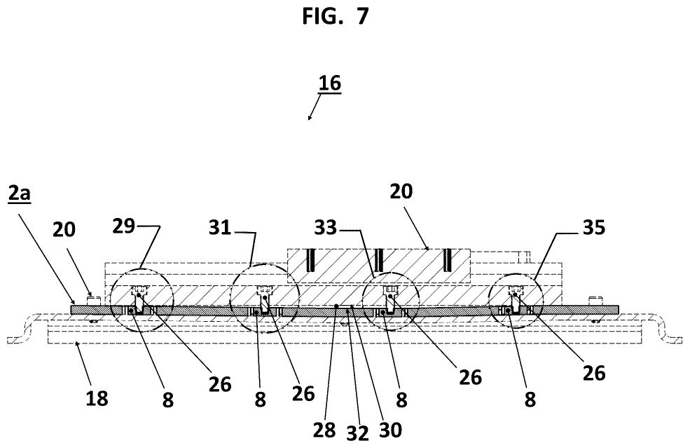

FIG. 7 is an elevational view in full section of the equipment assembly embodiment along line 27-27 in FIG. 6 wherein component of FIGS. 1, 2 and 3 is assembled in a condition before screws are tightened to specification according to invention.

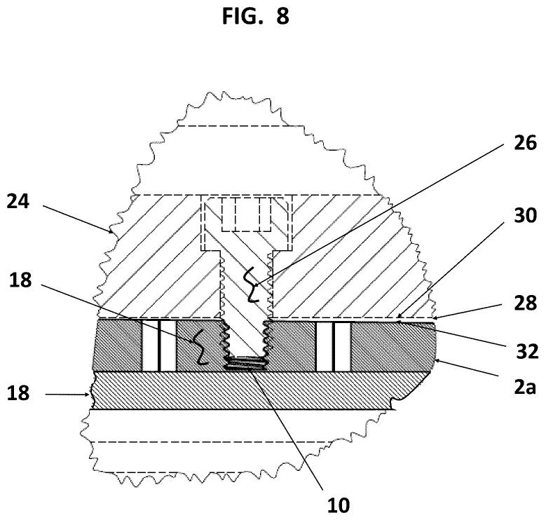

FIG. 8 is a detailed view of the area identified by line 29 in FIG. 7.

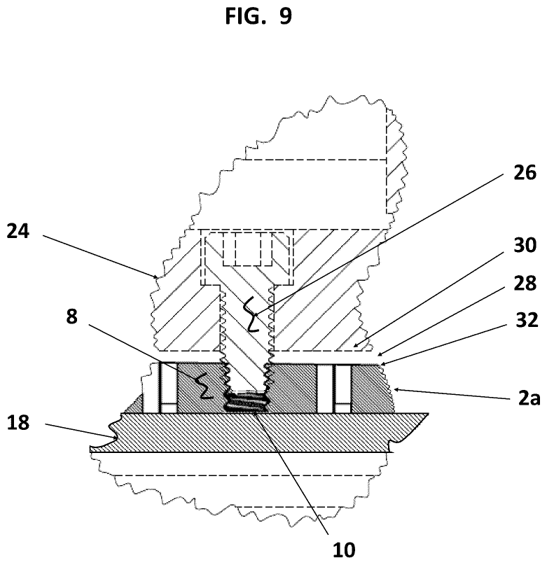

FIG. 9 is a detailed view of the area identified by line 31 in FIG. 7.

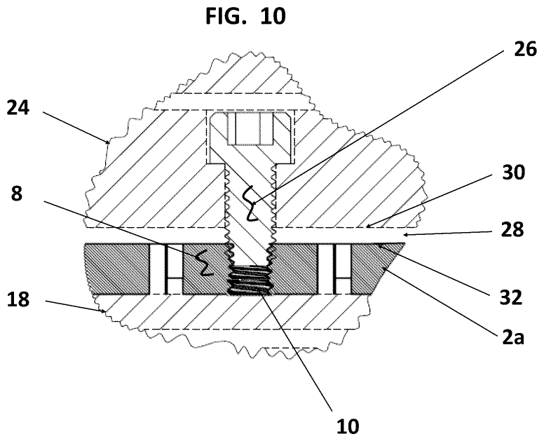

FIG. 10 is a detailed view of the area identified by line 33 in FIG. 7.

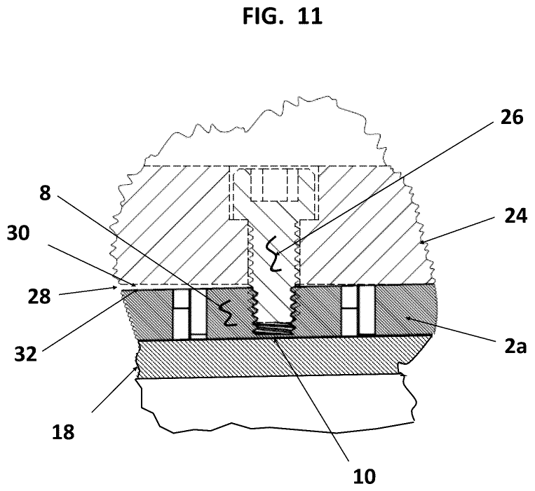

FIG. 11 is a detailed view of the area identified by line 35 in FIG. 7.

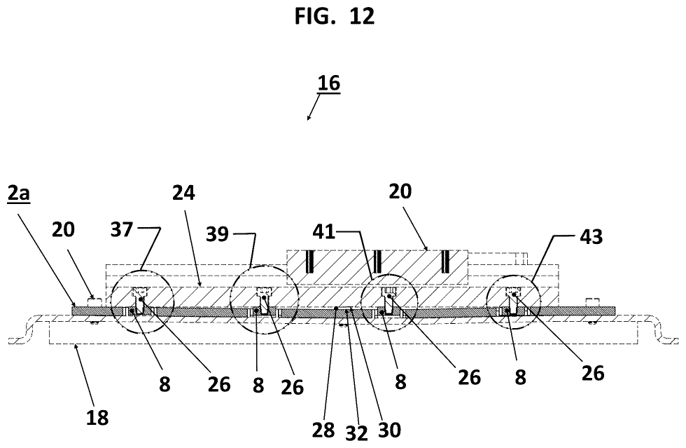

FIG. 12 is an elevational view in full section of the equipment assembly embodiment along line 27-27 in FIG. 6 wherein component of FIGS. 1, 2 and 3 is depicted as assembled in the condition which screws are tightened to specification according to this invention.

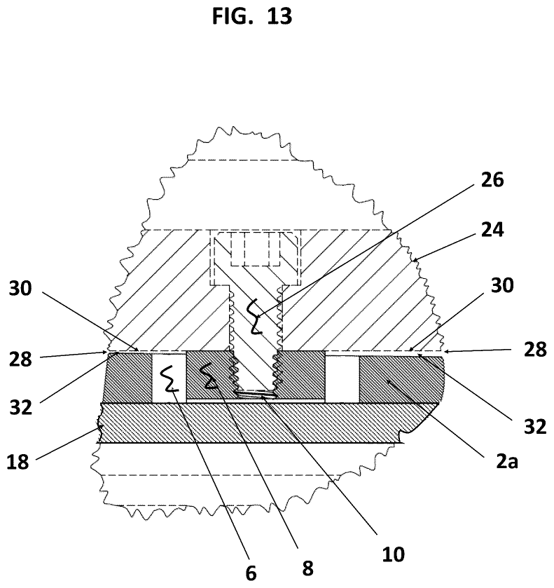

FIG. 13 is a detailed view of the area identified by line 37 in FIG. 12.

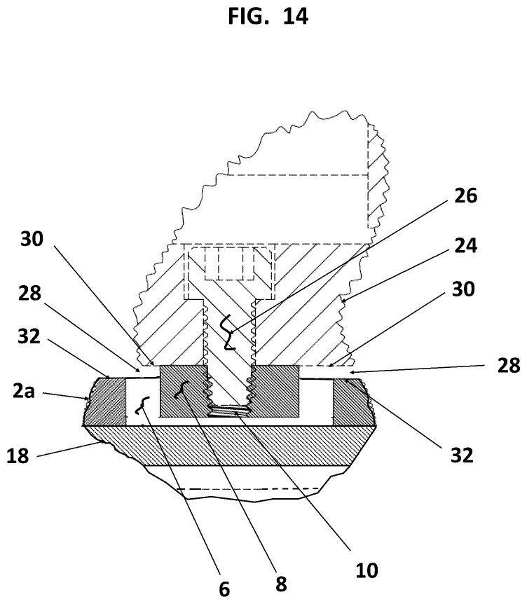

FIG. 14 is a detailed view of the area identified by line 39 in FIG. 12.

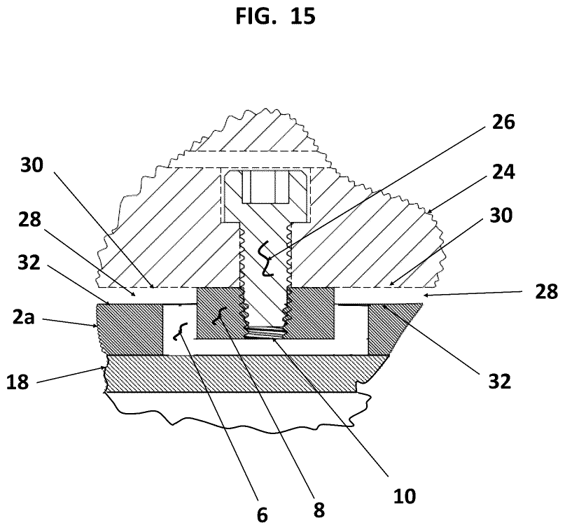

FIG. 15 is a detailed view of the area identified by line 41 in FIG. 12.

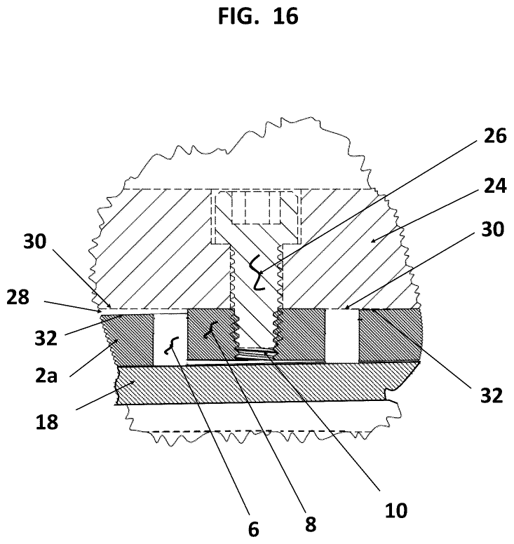

FIG. 16 is a detailed view of the area identified by line 43 in FIG. 12.

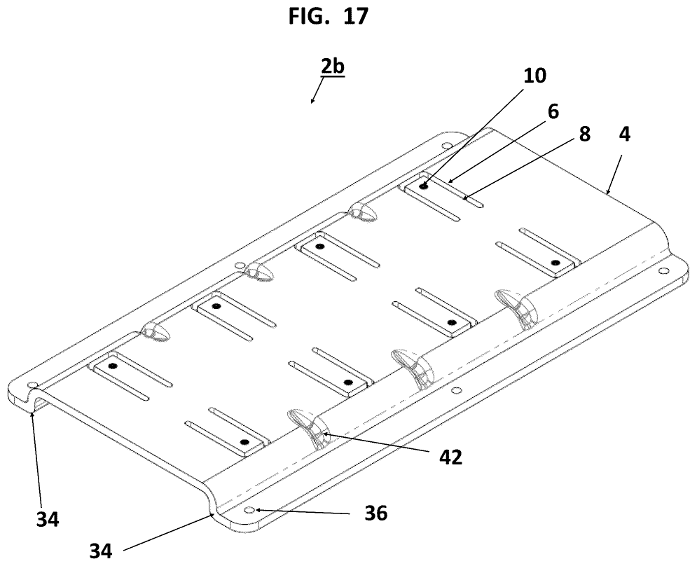

FIG. 17 is an isometric view of a second embodiment of the invention whereupon appendages are added as so to effectively elevate its rigid main support body to provide height and/or clearance underneath said rigid main support body according to this invention.

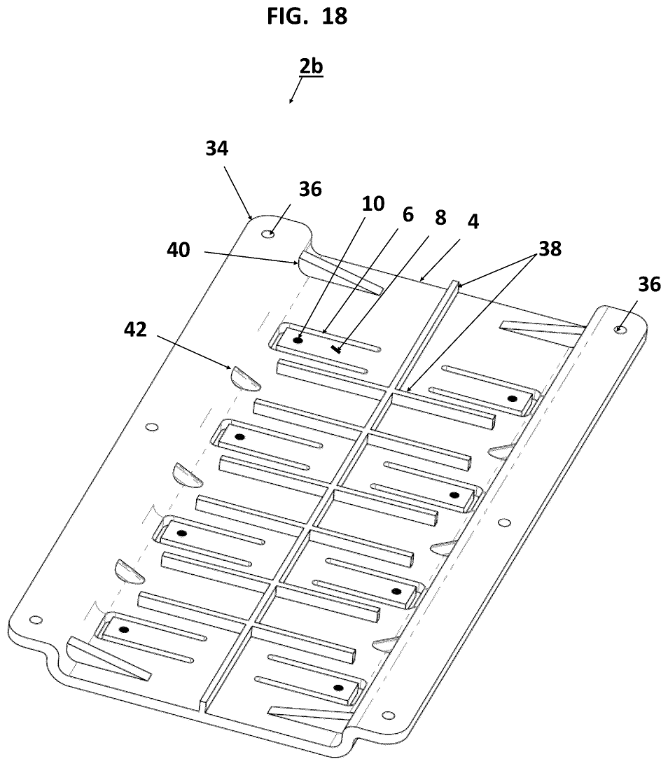

FIG. 18 is an isometric view of bottom surface of second embodiment component of FIG. 17 according to this invention.

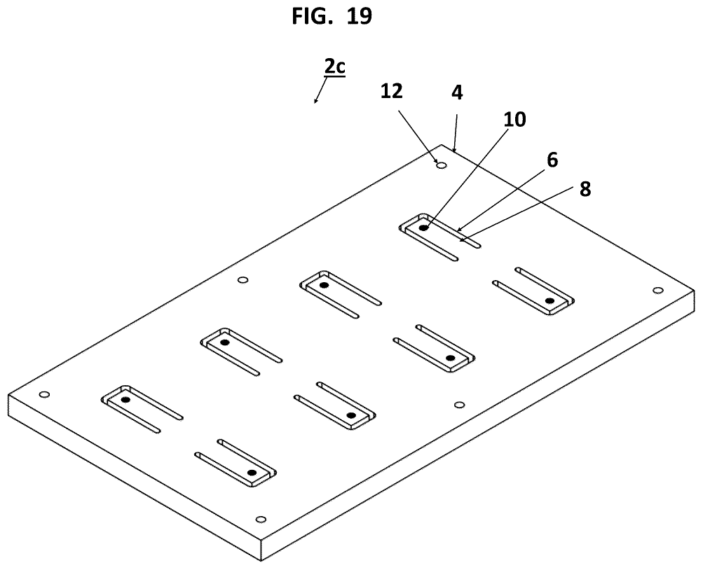

FIG. 19 is an isometric view of a third embodiment of the invention wherein thickness of rigid main support body is increased to effectively elevate and/or add strength according to this invention.

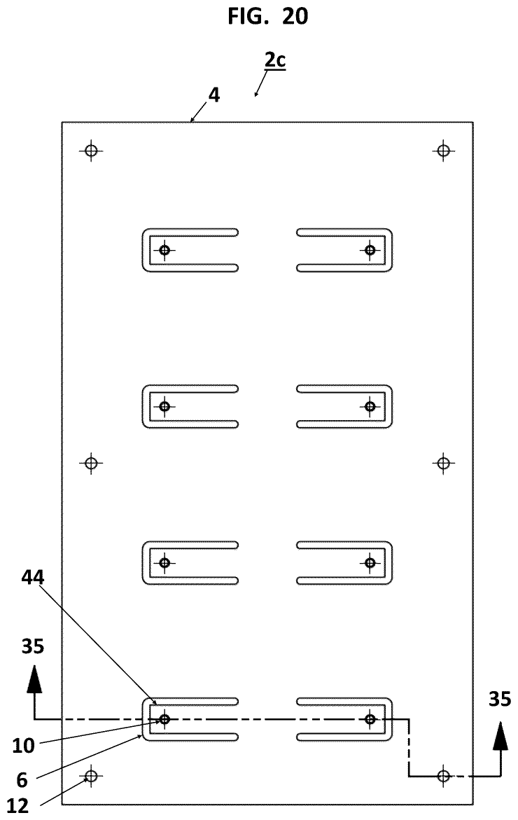

FIG. 20 is a top plan view of the component of FIG. 19. according to this invention.

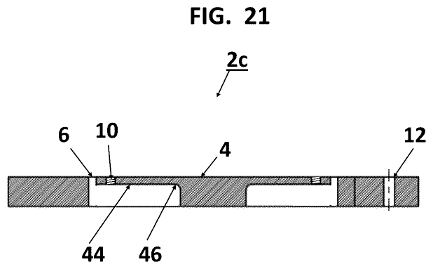

FIG. 21 is a front elevational view in full section depicting the component of FIGS. 19 and 20 along line 35-35 in FIG. 20 according to this invention.

### DETAILED DESCRIPTION OF THE PREFERRED EMBODIMENTS

With reference to FIG. 1, a Flat Surface Simulation Hardware Component (FSSHC) 2a in accordance with the invention particularly comprises a rigid main support body 4 that which is integrally configured with a plurality of thru-cut slots 6. Within each said slot is an integrally configured appendage in the form of a cantilevered beam 8. In particular, each beam extends from its fixed proximal end to its free distal end with each side of said beam maintaining an effective distance proximate to side of said slot so as to create free space on each unfixed sides as in common cantilevered beam design so as to let said beam perform not unlike a leaf spring. More particular said beam is configured with a particularly configured thru-cut hole 10 proximate to said distal end. Further particular, said rigid main support body is configured with a plurality of thru-cut holes 12 located proximate to outer edge of FSSHC. Said beam and hole elevational profiles are depicted in FIG. 3.

With reference to FIG. 4, said invention FSSHC 2a is shown installed into equipment assembly embodiment 16. Particularly FSSHC is installed upon the top surface of installation platform 18 using a plurality of screws 20 installed thru said holes 12 of which are configured at predetermined locations so as to be proximate inline axially with a plurality of holes configured into top surface of said installation platform at predetermined locations. Further with reference to FIG. 4 is the installation in progress of said linear motor (LM) 22. Screws 26 shall facilitate attaching said LM rail 24 to FSSHC.

Further, with reference to FIG. 5, said equipment embodiment 16 comprises linear motor (LM) 22 installed upon FSSHC with a plurality of screws 26. Particularly, said em component LM is particularly intimately captured to FSSHC via said rail 24 with a plurality of screws 26 of which directly integrally interface with corresponding said holes 10 configured appropriately in said 8 beams, so as to create an effective sandwich type assembly.

With reference to FIG. 6, each slot 6 can be identified as an indication said screws 26, said beams 8 with holes 10 are proximate axially aligned and integrally connected to corresponding holes configured within said LM rail. Further, to confirm said connection section cutting line 27-27 passes thru a number of particular screws 26 so as to provide an appropriate elevation view as FIG. 7.

With reference to FIG. 7 said screws 26 are depicted integrally connected to holes 10 in particular beams 8 in FSSHC 2a. Further, It appears rail is effectively located with its bottom surface intimate to top surface of FSSHC. It should be noted that, at this point in assembly, said screws 26 are only lightly tightened—not yet torqued down.

Further with particularly close examination with reference to FIG. 7 before tightening said screws 26 reveals a particular irregular space 28 between said rail bottom surface/edge 30 and said FSSHC top surface/edge 32. This space is result of irregular form of top surface said FSSHC which is configured to a standard high-low limit tolerance. Further analysis of said space with reference to details identified by lines 29, 31, 33, and 35 of which correspond to FIGS. 8, 9, 10, and 11 respectively. said space relationship between surface edges 30 and 32 is representative of a somewhat concave form of FSSHC top surface on which said rail rests. That is to mean the space is most great proximate to center of FSSHC as depicted in FIGS. 9 and 10 and gradually diminishes as it approaches proximate edge of FSSHC as depicted in FIGS. 8 and 11.

Now, ordinarily should beam strength of said equipment assembly 16 be greater than beam strength of said rail—tightening said screws 26 to full torque would most likely cause said rail to flex/deflect to a point where full torque is reached—thus causing failure of said LM upon test. However, the invention shall prevent the rail from deflecting by design whereof said beams shall deflect upward as screws 26 are tightened to full torque.

After screws 26 are torqued to specification, and with reference to FIGS. 12, 13, 14, 15 and 16 said beams are particularly depicted as each having deflected upward so as contact with bottom surface of rail. The result of which effectively is FSSHC has effectively simulated the condition of a perfectly flat surface, equilibrium of said system forces is achieved and risk of probability of failure associated with rail flex/deflection and subsequent torque requirements.

With reference to FIG. 17 and FIG. 18, a second embodiment 2b of the invention whereupon appendages 34 are added so as to provide mounting capability. A plurality of holes 36, not unlike holes 12 configured into said first embodiment 2a, provide effective mounting capability onto equipment chassis/frame assembly. Further said appendages facilitate elevating rigid main support body 4 to a predetermined height to facilitate a particular height requirement and/or so as to provide an effective clearance proximate below said rigid main support body 4 for packaging opportunity as an example.

Further with respect to FIG. 18, said appendages provide design opportunity to integrate features into underside of rigid main support body. Such features may increase moment of inertia (Mi) adding particular structural beam strength to said embodiment and or redirect load as needed. Additional strengthening features such as ribs 38 and/or gussets as depicted as both welded 40 and formed 42 may be integrated into said embodiment either by molding, casting, or forming depending upon particular manufacturing process chosen to produce the invention component FSSHC.

It is worth mentioning, with respect to forming and welding structural features into sheet metal fabrications, there is normally inherent risk of deformation when adding those features within a formed sheet-metal fabrication. However, because the invention itself effectively rectifies such deformation conditions—opportunity to design in strength enhancing features is actually an added benefit of the invention itself.

With reference to FIG. 19 a third embodiment of the invention 2c is configured such that rigid main support body 4 shall be configured for essentially any particular reason such as height or to increase its moment of inertia (Mi). With further reference to FIG. 20 and FIG. 21, a beam 44 with a profile 46 particularly configured so as to particularly modify said beam strength to facilitate particular required performance.

The preferred embodiment described herein fulfills the objects of the invention: Provide a component that simulates a uniformly flat installation platform so as to prevent deflection of component installed upon it and then to provide sufficient opposing force so as to allow screw torque requirements to be effectively met. Provide a component that eliminates the need for exceptionally tight tolerances to control surface condition of installation platform in order to comply with em component manufacturer quality/user requirements. Provide a component that is easy to design and install with a system design. Provide a component that lends itself easily to low, medium, and high-volume manufacturing. Provide a component that facilitates easy design, specification, modification, and adaptability to equipment design. So as to mitigate high-risk of probability of failure in Design-FMEA. Provide a component that facilitates easy manufacturing, inspection, and assembly so to mitigate high risk of probability of failure Process-FMEA. Provide a component that is very cost-effect to fabricate, inspect/validate and install. So as to mitigate the risk of defective products entering assembly lines which further reduces secondary costs impacting operations and quality not to mention customer service and sales.

The invention has been described with particular reference to the preferred embodiments, but it will be understood that variations and modifications within the spirit and scope of the invention may occur to those skilled in the art to which the invention pertains.

What is claimed is:

1. A flat surface simulation hardware component for providing a flat form condition surface to facilitate installation of electro-mechanical components in compliance with manufacturer installation requirements.
a main support body comprising a plurality of thru-cut polygonal slots configured in a predetermined pattern where within each said slot is a particularly configured appendage configured as a common cantilevered beam with its proximal end integrally part of said body while said beam extends a predetermined distance to its distal end in which is configured a thru-cut hole of which is particularly configured so as to align with corresponding mounting holes within said em component of which shall be attached at assembly with appropriate hardware.
a plurality of thru-cut holes, configured in a predetermined pattern to facilitate locating and fastening invention to equipment chassis/frame or installation platform component therein.

1. The flat surface simulation hardware component of claim 1 wherein said main support body is particularly configured to have beam strength of greater value than the combined beam strength of all said beams/appendages integrated to said body so as to configure said main support body to resist deflecting as said beams shall deflect upon installation of em component

2. The flat surface simulation hardware component of claim 1 wherein cantilevered beams are particularly configured so that their combined beam strength is less than the beam strength of said em component so as to not cause said em component to deflect upon installation.

3. The flat surface simulation hardware component of claim 1 wherein cantilevered beams are particularly configured with respect to beam strength that a predetermined deflection distance can be attained and held indefinitely without risk of yield during installation of component and/or result in plastic deformation over its life as installed within an equipment installation.

4. The flat surface simulation hardware component of claim 1 configured so as to simulate a particularly flat form surface condition by configuring beams so as they will deflect upward upon tightening component installation screws into holes configured within distal end of cantilevered beam such to create opposing force that shall keep em component from deflecting which would increase risk of probable failure.

5. The flat surface simulation hardware component of claim 1 configured so as to simulate a particularly flat form surface condition by configuring beams so as they will deflect upward upon tightening component installation screws into holes configured within distal end of cantilevered beam such to create opposing force that shall allow installer to torque screws to manufacturer specification which shall mitigate high risk of failure due to movement of em component from
